(19) United States
(12) Patent Application Publication
(10) Pub. No.: US 2005/0040478 A1
(43) Pub. Date: Feb. 24, 2005

(54) Novel non-crystalline oxides for use in microelectronic, optical, and other applications

(76) Inventors: Gerald Lucovsky, Cary, NC (US); Gregory N. Parsons, Raleigh, NC (US)

Correspondence Address: MYERS BIGEL SIBLEY & SAJOVEC, PO BOX 37428, RALEIGH, NC, 27627, US

(21) Appl. No.: 10/924,541

(22) Filed: Aug. 24, 2004

Related U.S. Application Data
(62) Division of application No. 09/891,552, filed on Jun. 25, 2001, now Pat. No. 6,787,861.

(51) Int. Cl. H01L 29/76

(52) U.S. Cl. 257/410

(57) ABSTRACT

The invention relates to non-crystalline oxides of formulas (I) and (II), and methods of forming the same, along with field effect transistors, articles of manufacture, and microelectronic devices comprising the non-crystalline oxides.

### CROSS-REFERENCE TO RELATED APPLICATIONS

The present application claims priority to U.S. Provisional Application No. 60/214,285 filed Jun. 26, 2001, the disclosure of which is incorporated herein by reference in its entirety.

### FIELD OF THE INVENTION

The invention generally relates to oxide-containing materials, along with articles of manufacture comprising the same, and methods of forming the same.

### BACKGROUND OF THE INVENTION

As device dimensions are scaled according to the 1999 Technology Roadmap for Semiconductors, 1999 Edition (http://public.itrs.net), the equivalent gate oxide thickness, EOT, should decrease below about 1.5 nm. At this silicon dioxide (SiO₂) thickness, the direct tunneling current for a one volt potential drop across the oxide is typically greater than 1 A/cm². Such a volt potential drop is potentially disadvantageous in that it begins to reduce the ratio of on- to off-state current in a field effect transistor. In order to attempt to reduce the off-state leakage currents due to tunneling through SiO₂ and maintain a capacitance that is equivalent to that obtained with a SiO₂ dielectric with a physical thickness of 1.5 nm and below, alternative high-k dielectrics are being investigated. See e.g., J. Robertson, J. Vac. Sci. Technol. B 18(3) (2000) and G. D Wilk, et al., J. Appl. Phys. 89, 5243 (2001). These high-k alternative dielectrics are potentially capable of providing the required levels of EOT for device scaling at larger physical thickness. Thus, a pathway for the potential reduction of tunneling current is provided. Other factors such as conduction band offset energies also are believed to play a role in influencing tunnel leakage, and these offset energies generally decrease with increasing k.

Recently, aluminum oxide has been the focus of several studies. Klein et al. Appl. Phys. Lett. 75, 4001 (1999 ) propose the deposition of aluminum oxide with a CVD growth method. This reference proposes a silicate layer being present at the interface on aluminum oxide and silicon, as measured by nuclear resonance profiling (NRP) and X-ray photoelectron spectroscopy (XPS). Gusev et al. Appl. Phys. Lett. 76, 176 (2000) propose atomic layer CVD (ALCVD) where they investigated both the physical and electrical properties of an aluminum oxide layer. Gusey et al. propose that it is possible to deposit aluminum oxide on hydrogen-terminate silicon without forming an interfacial layer using NRP, medium energy ion scattering (MEIS), and high-resolution transmission electron microscopy (TEM).

Transistors with an equivalent gate oxide thickness of 0.96 nm with aluminum oxide as the material are proposed by Chin et al. Tech. Dig. VLSI Symp, 16 (2000). Chin et al. proposes that these devices have a Dᵢₜ value greater than or equal to 3¹⁰ cm⁻² and a positive flat band shift, indicating a negative fixed charge. Buchanan et al., Tech. Dig. Intl. Electron Devices Meet, 223 (2000) propose an nMOSFET formed by ALCVD Al₂O₃ with 0.08 μm gate lengths. This reference also proposes a negative fixed charge for devices with an equivalent oxide thickness of 1.3 nm.

Notwithstanding the above, there remains a need in the art for oxide materials that may be used in semiconductor devices which have the potential to reduce direct tunneling current in the devices.

### SUMMARY OF THE INVENTION

The present invention addresses the inadequacies of the prior art. In one aspect, the invention provides a non-crystalline oxide represented by the formula (I):
—(ABO₄)ₓ(MₙOₘ)₁₋ₓ— (I)
wherein:
A is an element selected from Group IIIA of the periodic table;
B is an element selected from Group VB of the periodic table;
O is oxygen;
M is an element selected from either Group IIIB or Group IVB of the periodic table; and
n ranges from about 0.5 to about 2.5, m ranges from about 1.5 to about 3.5, and x is a fraction ranging from 0 to 1.

In another aspect, the invention provides a a non-crystalline oxide represented by the formula (II):
—(AlO₂)ⱼ(MₙOₘ)ₖ— (II)
wherein:
Al is aluminum;
O is oxygen;
M is an element selected from either Group IIIB or Group IVB of the periodic table; and
j ranges from about 0.5 to about 4.5; k is equal to about 1; n ranges from about 0.5 to about 2.5, and m ranges from about 1.5 to about 3.5.

In another aspect, the invention provides methods of forming a non-crystalline oxide represented by the formulas (I) and (II) as described in greater detail hereinbelow.

In another aspect, the invention provides a field effect transistor. The field effect transistor comprises an integrated circuit substrate having a first surface, source and drain regions in the substrate at the first surface in a spaced apart relationship, and a gate insulating layer on the substrate at the first surface between the spaced apart source and drain regions. The gate insulating layer comprises any of the non-crystalline oxides represented by formulas (I) or (II) described hereinbelow.

These and other aspects and advantages of the present invention are set forth hereinbelow.

### BRIEF DESCRIPTION OF THE DRAWINGS

FIGS. 1a and 1b illustrate layers used in microelectronic devices employing the non-crystalline oxides of the invention.

### DETAILED DESCRIPTION OF THE PREFERRED EMBODIMENTS

The invention will now be described in detail with reference to the following embodiments set forth herein. It should be appreciated that these embodiments merely serve to illustrate the invention and do not limit the scope of the invention. In the drawings, like numbers refer to like elements throughout. In addition, the term “on” is construed to mean a structure actually contacting an adjoining structure, or in close proximity to the adjoining structure without actually contacting it.

In one aspect, the invention provides a non-crystalline oxide represented by the formula (I):
—(ABO₄)ₓ(MₙOₘ)₁₋ₓ— (I)
wherein:
A is an element selected from Group IIIA of the periodic table;
B is an element selected from Group VB of the periodic table;
O is oxygen;
M is an element selected from either Group IIIB or Group IVB of the periodic table; and n ranges from about 0.5 to about 2.5, m ranges from about 1.5 to about 3.5, and x is a fraction ranging from 0 to 1.

In one embodiment encompassing the oxide represented by formula (I), A is aluminum (Al), B is tantalum (Ta), M is selected from halfnium (Hf) or zirconium (Zr), n is 1, m is 2, and x is less than 0.25.

In another embodiment encompassing the oxide represented by formula (I), A is aluminum (Al), B is tantalum (Ta), M is selected from yttrium (Y) or lanthanum (La), n is 2, m is 3, and x is less than 0.25.

In another aspect, the invention provides a non-crystalline oxide represented by the formula (II):
—(AlO₂)ⱼ(MₙOₘ)ₖ— (II)
wherein:
Al is aluminum;
O is oxygen;
M is an element selected from either Group IIIB or Group IVB of the periodic table; and
j ranges from about 0.5 to about 4.5; k is equal to about 1; n ranges from about 0.5 to about 2.5, and m ranges from about 1.5 to about 3.5.

In one embodiment regarding the oxide represented by formula (II), M is selected from halfnium (Hf) or zirconium (Zr), n is 1, m is 2, j is 4, and k is 1.

In another embodiment regarding the oxide represented by formula (II), M is selected from yttrium (Y) or lanthanum (La), n is 2, m is 3, j is 3, and k is 1.

The novel materials of the invention are believed to have bonding properties, and hence electrical and optical properties, potentially similar to those of thin film silicates. In addition, this novel class of materials offers potential properties that may not be realized in conventional silicate alloys, and therefore opens new applications in microelectronics and other technologies.

This invention proposes novel non-crystalline oxides. In the non-crystalline oxides of formula (I), the SIO₂ component of the silicates is replaced by a Group IIIA-VA or B analog network structure such as AlPO₄, or AlTaO₄ as described in Ser. No. 09/434,607 filed Nov. 5, 1999, the disclosure of which is incorporated herein by reference in its entirety (“the '607 application”). Although not intending to be bound by theory, alloying these binary alloys with additional metal oxides that are more ionic that Al₂O₃ is believed to introduce positive metal ions which interrupt or modify the Al₂¹⁻ and (P or Ta)O₂¹⁺ network of the host oxide and provide bonding that is qualitatively similar to the SiO₂₋ based silicates. Other group three metal atoms with electronegativities greater than 1.6, e.g., Ga, may also be substituted for Al, and other group VA or B elements for Ta, e.g., As, Sb, and Nb and the like.

The non-crystalline oxides of formula (II) corresponds to stoichiometric or near stoichiometric aluminates, wherein the network component is believed to be significantly reduced by alloying with a more ionic metal oxide, such as Zr(Hf)O₂ or Y(La)₂O₃. Although not intending to be bound by theory, it is believed that the rational for these structures derives from the vast number of alumino-silicate mineral species that exist in nature. The number of positive ions necessary for compensating the AlO₂¹⁻ groups may be determined by the number of these groups. For example, representative oxides in the second group include: Zr(Hf)(AlO₂)₄ and Y(La)(AlO₂)₃. These can also be described as mixed oxides as Zr(Hf)O₂(Al₂O₃)₂ and Y(La)₂O₃(Al₂O₃)₃. These materials can be customized to provide either neutral or charged bonding arrangements with elemental or compound semiconductors.

In addition to the above, the invention relates to methods of forming the non-crystalline oxides of the invention. More particularly, in one aspect, the invention provides a method of forming a non-crystalline oxide represented by the formula (I):
—(ABO₄)ₓ(MₙOₘ)₁₋ₓ— (I)
wherein A is an element selected from Group IIIA of the periodic table, B is an element selected from Group VB of the periodic table, O is oxygen, M is an element selected from either Group IIIB or Group IVB of the periodic table, n ranges from about 0.5 to about 2.5, m ranges from about 1.5 to about 3.5, and x is a fraction ranging from 0 to 1. The method comprises delivering a gaseous source comprising element A, a gaseous source comprising element B, a gaseous source comprising element M, and a gaseous source comprising oxygen on a substrate such that the gaseous source comprising element A, the gaseous source comprising element B, the gaseous source comprising element M, and the gaseous source comprising oxygen react to form the non-crystalline oxide represented by the formula (I).

Gaseous sources containing more than one element per source are encompassed by the invention (e.g., mixed sources). In a preferred embodiment, the elements A, B and M are delivered in amounts necessary (i.e., sufficient) for achieving chemical stoichiometry, i.e., deposited thin films with the required ratios of network and network modifier ions to achieve stoichiometry of the their constituent oxides. Preferably, the gaseous sources comprising oxygen contain a sufficient amount of oxygen such that the elements A, B and M are completely oxidized. In one embodiment, the delivery step is carried out as a deposition.

The oxygen which is present in the gaseous source of the above method of forming the non-crystalline oxide represented by formula (I) may be selected from a number of species. Exemplary species include, without limitation, oxygen atoms, oxygen ions, oxygen metastables, oxygen molecular ions, oxygen molecular metastables, compound oxygen molecular ions, compound oxygen metastables, compound oxygen radicals, and mixtures thereof. In a preferred embodiment, the gaseous source comprising oxygen comprises O₂ or N₂O. It is particularly preferred that the formation of the non-crystalline oxides take place in non-equilibrium chemical environments.

The depositing step of the method of forming the non-crystalline oxide represented by formula (I) may occur by various techniques. In one preferred embodiment, the depositing step includes a remote plasma-enhanced chemical vapor deposition occurring in a reactor, and wherein the remote-plasma-enhanced chemical vapor deposition comprises subjecting the gaseous source comprising oxygen to radio-frequency plasma-excitation or microwave frequency plasma-excitation. The gaseous source comprising oxygen further comprises a rare gas element, and the gaseous oxygen-containing source is injected into the reactor upstream relative to the gaseous source comprising element A, the gaseous source comprising element B, and the gaseous source comprising element M.

In another aspect, the invention provides a method of forming a non-crystalline oxide represented by the formula (II):
—(AlO₂)ⱼ(MₙOₘ)ₖ— (II)
wherein:

Al is aluminum, O is oxygen, M is an element selected from either Group IIIB or Group IVB of the periodic table, j ranges from about 0.5 to about 4.5, k is equal to about 1, n ranges from about 0.5 to about 2.5, and m ranges from about 1.5 to about 3.5. The method comprises delivering a gaseous source comprising aluminum, a gaseous source comprising element M, and a gaseous source comprising oxygen on a substrate such that the gaseous source comprising aluminum, the gaseous source comprising element M, and the gaseous source comprising oxygen react to form the non-crystalline oxide represented by the formula (II).

In a preferred embodiment, the method of forming the non-crystalline oxide represented by formula (II) is preferably carried out in a manner such that elements aluminum and M are present in amounts sufficient to achieve chemical stoichiometry, with the term “chemical stoichiometry” being defined herein. Preferably, the gaseous source comprising oxygen contains a sufficient amount of oxygen such that the elements aluminum and M are completely oxidized.

In a preferred embodiment, the oxygen employed in the method of forming a non-crystalline oxide represented by the formula (II) may be selected from various species. Preferably, the oxygen in the gaseous source is selected from the group consisting of oxygen atoms, oxygen ions, oxygen metastables, oxygen molecular ions, oxygen molecular metastables, compound oxygen molecular ions, compound oxygen metastables, compound oxygen radicals, and mixtures thereof. In a preferred embodiment, the gaseous source comprising oxygen comprises O₂ or N₂O. Mixtures of the above can also be employed. It is particularly preferred that the formation of the non-crystalline oxide represented by formula (II) take place in a non-equilibrium chemical environment.

The depositing step of the method of forming the non-crystalline oxide represented by formula (II) may be carried out according to various techniques. In one preferred embodiment, the depositing step is a remote plasma-enhanced chemical vapor deposition that occurs in a reactor. Preferably, the remote-plasma-enhanced chemical vapor deposition comprises subjecting the gaseous source comprising oxygen to radio-frequency plasma-excitation or microwave frequency plasma-excitation. The gaseous source comprising oxygen further comprises a rare gas element and the gaseous oxygen-containing source is injected into the reactor upstream relative to the gaseous source comprising aluminum and the gaseous source comprising element M.

Various gaseous sources comprising any of the applicable elements for the above methods may be employed for the purposes of the invention. Examples of gaseous sources comprising the elements may include, but are not limited to, alkoxide compounds, organometallic compounds, inorganic compounds, and mixtures thereof. Preferably, the alkoxide compound is selected from the group consisting of an ethoxide, a propoxide, and a butoxide. When the element is aluminum, it is preferred that the gaseous source comprises trimethyl aluminum. Other gaseous sources comprising the elements can be used such as organo-metallic source gases including those that are capable of producing the desired binary oxides (e.g., diketonates) along with other organo-metallics that contain metal-oxygen bonds. Other inorganic sources of the elements can be employed such as halides and nitrates. The gaseous sources comprising the element(s) can be derived through the evaporation of respective liquid sources comprising these elements, particularly in embodiments in which the deposition involves a physical deposition or a plasma chemical vapor deposition process.

The gaseous sources comprising the elements which are employed in the methods of the invention may further comprise other components such as, for example, inert gases (e.g., argon (Ar) helium (He), or other noble gases, as well as mixtures thereof.

As alluded to hereinabove, a number of deposition techniques can be used in forming the non-crystalline oxides represented by formulas (I) and (II) of the invention. Examples of these techniques include, without limitation, those described in the '607 application. Exemplary techniques include, but are not limited to, a laser-assisted chemical vapor deposition, a direct or remote plasma assisted chemical vapor deposition, a electron cyclotron resonance chemical vapor deposition, and a reactive physical vapor deposition. In one embodiment, a remote plasma assisted chemical deposition is employed. Various reactive physical vapor depositions can be used such as, for example, a thermal evaporation, an electron beam evaporation, a parallel plate radio frequency (rf) sputtering, a direct current (dc) sputtering, a radio frequency (rf) magnetron sputtering, and a direct current (dc) magnetron sputtering. A reactive physical vapor deposition may also occur in the form of an atomic layer absorption process. The invention is often carried out by remote plasma-enhanced chemical vapor deposition (i.e., REPCVD).

The methods of the invention may be carried out under any number of temperature and pressure conditions. The methods of the invention may be carried out using known equipment, including, for example, a suitable reactor (e.g., reaction chamber or vessel). In one embodiment, alkoxide liquids comprising elements are injected into a reactor downstream from a remote radio-frequency excited plasma. Preferably, the alkoxides are liquids at room temperature, but at the temperature range employed in the reactor have sufficient levels of vapor to be transported into the reactor. A microwave plasma may be employed if so desired. In one embodiment, the processing pressure may range from about 200 to about 400 mTorr and the temperature of the substrate upon which the oxides are formed ranges from about 200° C. to about 300° C. In a preferred embodiment, silane may be used as a precursor of Si and metal organics for Al and transition metals such as, for example, Ta, Zr, Hf, Y, and the like. An oxygen source encompassing those, without limitation, set forth herein, is preferably delivered upstream through plasma, diluted with He. The silane and metal organics are preferably delivered downstream. In other various embodiments, nitrate sources can be employed for Ti, Hf, and Zr, e.g., Zr(NO₃)₄. Other techniques include, without limitation, atomic layer deposition using water as the oxidizing agent, and silane metal organic sources for other constituents. An example of a source gas for Zr is Zr t-butoxide. Source gases for Ta and Al as well as other metals can also be used.

In another aspect, the invention relates to a field effect transistor. The field effect transistor comprises an integrated circuit substrate having a first surface, source and drain regions in the substrate at the first surface in a spaced apart relationship, a gate insulating layer on the substrate at the first surface between the spaced apart source and drain regions. The gate insulating layer comprising a non-crystalline oxide represented by the formula (I):
—(ABO₄)ₓ(MₙOₘ)₁₋ₓ— (I)
wherein:
A is an element selected from Group IIIA of the periodic table;
B is an element selected from Group VB of the periodic table;
O is oxygen;
M is an element selected from either Group IIIB or Group IVB of the periodic table;
n ranges from about 0.5 to about 2.5;
m ranges from about 1.5 to about 3.5 ; and
x is a fraction ranging from 0 to 1.

The non-crystalline oxide represented by the formula (I) employed in the field effect transistor may include, without limitation, all species described by this formula.

In one embodiment, the field effect transistor which employs the non-crystalline oxide represented by formula (I) comprises a material selected from the group consisting of a Group III-V binary alloy, a Group III-V quaternary alloy, a Group III-nitride alloy, and combinations thereof.

In another embodiment, the substrate of the above field effect transistor comprises a Group III-V binary alloy selected from the group consisting of (Ga,Al)As, (In,Ga)As, and combinations thereof.

In another aspect, the invention also provides a field effect transistor which employs a non-crystalline oxide represented by the formula (II). The field effect transistor comprises an integrated circuit substrate having a first surface, source and drain regions in the substrate at the first surface in a spaced apart relationship, a gate insulating layer on said substrate at the first surface between said spaced apart source and drain regions, the gate insulating layer comprising a non-crystalline oxide represented by the formula (II):
—(AlO₂)ⱼ(MₙOₘ)ₖ— (II)
wherein:

Al is aluminum, O is oxygen, M is an element selected from either Group IIIB or Group IVB of the periodic table, j ranges from about 0.5 to about 4.5, k is equal to about 1, n ranges from about 0.5 to about 2.5, and m ranges from about 1.5 to about 3.5.

In one embodiment, the substrate of the field effect transistor which employs a non-crystalline oxide of formula (II) comprises a material selected from the group consisting of a Group III-V binary alloy, a Group III-V quaternary alloy, a Group III-nitride alloy, and combinations thereof.

In another embodiment, the substrate of the field effect transistor which employs the non-crystalline oxide of formula (II) comprises a Group III-V binary alloy selected from the group consisting of (Ga,Al)As, (In,Ga)As, and combinations thereof.

Examples of proposed applications for the novel non-crystalline oxides of the invention include, without limitation, integration of the single layer or stacked non-crystalline oxides into gate stacks for NMOS, PMOS or CMOS applications involving Si, SiC and other compound semiconductors such as the III-V arsenides, antimonides, nitrides or phosphides, etc. In various embodiments, the layers can also be used in a number of articles of manufacture that comprise the non-crystalline oxides represented by the formulas (I) and (II). Examples of articles of manufacture include, without limitation, passivation layers on other types of devices, e.g., photoconductors, photodiodes, light-emitting diodes, lasers, sensors, and micro-mechanical (MEMS) devices. Additionally, for example, they also can be used in devices with metal electrodes, such as spin-valves, or metal interface amplifiers. They also can be used for articles used sensor and catalysis applications.

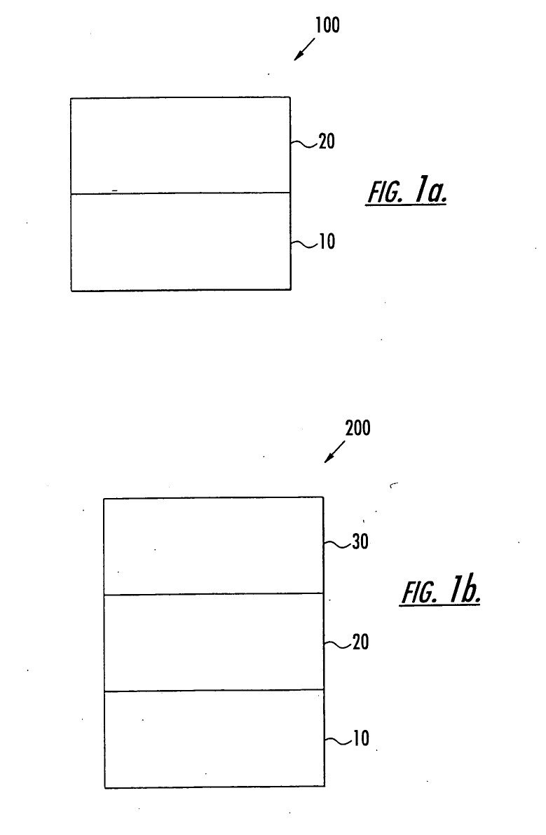

The non-crystalline oxides of the invention may be used in a number of ways in various stacked structures that are employed in a variety of microelectronic devices such as, without limitation, those described herein. Examples of such structures include 100 and 200 as depicted in the drawings. For example, in one embodiment of a stacked structure depicted in FIG. 1a, interfacial layer 10 may comprise any number of appropriate materials such as, in one illustration, the oxides recited in the '607 application (e.g., AlTaO₄). Additionally, the interfacial layer 10 may comprise a non-crystalline oxide of formula (I) described herein or a non-crystalline oxide of formula (II) described herein. Any combinations of the above materials can be employed in interfacial layer 10.

Referring again to FIG. 1a, present on the interfacial layer 10 is base layer 20. The base layer 20 may comprise a non-crystalline oxide of the formula (I) described herein, a non-crystalline oxide of the formula (II) described herein, or any combination of these two materials, as well as any of the oxides disclosed in the '607 application. In another embodiment, the base layer 20 may comprise an oxide of the formula (III):
D(AlO₂)_{z} (III)

wherein D is Group IIIB or IVB oxide and z is an integer, preferably 3 or 4. In preferred embodiments, the oxide of formula may be selected from Hf(AlO₂)₄ or Y(AlO₂)₃, as well as combinations thereof. Combinations of any of the above disclosed oxides can be utilized in the base layer 20, as well as others.

In addition, as shown in FIG. 1b, a surface/interface layer 30 can be employed on top of base layer 20. In one embodiment, layer 30 may comprise nitrogen. In other embodiments, layer 30 may comprise any number of oxides such as, without limitation, an oxide of the second group (i.e., Group (II)) described herein (e.g., Zr(Hf)(AlO₂)₄ or Y(La)(AlO₂)₃), an oxide disclosed in the '607 application (e.g., TiAlO₄) as well as others, alone or in combination with nitrogen. In various embodiments, metal is on top of surface/interface layer 30. Accordingly, elements employed in various oxides may be selected to match the contacting metal. Combinations. of any of the above materials can be employed in layer 30.

One novel and unusual feature is a recognition that macroscopically neutral covalent random network structures comprised of alternative charged network groups can have properties tailored by the addition of other metal ions, as in conventional silicates with a neutral SiO₂ network forming group. A second novel and unusual feature is the identification of networks that have constituents which can provide neutral or charged network bonding at interfaces according to their composition. The disclosure of these materials allows for new potential options for integration into devices, most noteworthy is the ability to control the nature of the band bending at elemental and compound semiconductor interfaces. Surface modification also allows for unique opportunities for sensors and/or catalytic applications. As such, the novel materials of the invention can be integrated into devices with elemental or compound semiconductors as gate dielectric or passivation layers for microelectronic or optical applications. They can also be used metals in spin valve devices and metal interface amplifiers. Finally, they provide pathways to surface modification for applications in sensing and catalysis.

The invention has been described in detail with respect to the embodiments set forth hereinabove. It should be appreciated that the embodiments are merely set forth to illustrate the invention, and do not serve to limit the invention as defined by the claims.

The invention has been described with respect to various embodiments set forth in the specification and drawings. It should be appreciated that these embodiments are for illustrative purposes only, and do not limit the scope of the invention as described by the claims that follow.

1-3. (Canceled)

4. A method of forming a non-crystalline oxide represented by the formula (I):
—(ABO₄)ₓ(MₙOₘ)₁₋ₓ—
wherein A is an element selected from Group IIIA of the periodic table, B is an element selected from Group VB of the periodic table, O is oxygen, M is an element selected from either Group IIIB or Group IVB of the periodic table, n ranges from about 0.5 to about 2.5, m ranges from about 1.5 to about 3.5, and 0<x<1, said method comprising:
delivering a gaseous source comprising element A, a gaseous source comprising element B, a gaseous source comprising element M, and a gaseous source comprising oxygen on a substrate such that the gaseous source comprising element A, the gaseous source comprising element B, the gaseous source comprising element M, and the gaseous source comprising oxygen react to form the non-crystalline oxide.

5. The method according to claim 4, wherein elements A, B, and M are present in amounts sufficient to achieve chemical stoichiometry, and wherein the gaseous source comprising oxygen contains a sufficient amount of oxygen such that the elements A, B, and M are completely oxidized.

6. The method according to claim 4, wherein the oxygen in the gaseous source comprising oxygen-containing source is selected from the group consisting of oxygen atoms, oxygen ions, oxygen metastables, oxygen molecular ions, oxygen molecular metastables, compound oxygen molecular ions, compound oxygen metastables, compound oxygen radicals, and mixtures thereof.

7. The method according to claim 4, wherein the gaseous source comprising oxygen comprises O₂ or N₂O.

8. The method according to claim 4, wherein said delivering step is a remote plasma-enhanced chemical vapor deposition occurring in a reactor, and wherein the remote-plasma-enhanced chemical vapor deposition comprises:
subjecting the gaseous source comprising oxygen to radio-frequency plasma-excitation or microwave frequency plasma-excitation, the gaseous source comprising oxygen further comprising a rare gas element;
wherein the gaseous oxygen-containing source is injected into the reactor upstream relative to the gaseous source comprising element A, the gaseous source comprising element B, and the gaseous source comprising element M.

9. The method according to claim 4, wherein A is aluminum (Al), B is tantalum (Ta), M is hafnium (Hf) or zirconium (Zr), n is 1, m is 2, and x is less than 0.25.

10. The method according to claim 4, wherein A is aluminum (Al), B is tantalum (Ta), M is yttrium (Y) or lanthanum (La), n is 2, m is 3, and x is less than 0.25.

11-26. (Canceled)

27. A method of forming a non-crystalline oxide represented by the formula (II):
—(AlO₂)ⱼ(MₙOₘ)ₖ— (II)
wherein:
Al is aluminum, O is oxygen, M is an element selected from either Group IIIB or Group IVB of the periodic table, j ranges from about 0.5 to about 4.5, k is equal to about 1, n ranges from about 0.5 to about 2.5, and m ranges from about 1.5 to about 3.5, said method comprising:
delivering a gaseous source comprising aluminum, a gaseous source comprising element M, and a gaseous source comprising oxygen on a substrate such that the gaseous source comprising aluminum, the gaseous source comprising element M, and the gaseous source comprising oxygen react to form the non-crystalline oxide.

28. The method according to claim 27, wherein elements aluminum and M are present in amounts sufficient to achieve chemical stoichiometry, and wherein the gaseous source comprising oxygen contains a sufficient amount of oxygen such that the elements aluminum and M are completely oxidized.

29. A method according to claim 27, wherein the oxygen in the gaseous source comprising oxygen-containing source is selected from the group consisting of oxygen atoms, oxygen ions, oxygen metastables, oxygen molecular ions, oxygen molecular metastables, compound oxygen molecular ions, compound oxygen metastables, compound oxygen radicals, and mixtures thereof.

30. The method according to claim 27, wherein the gaseous source comprising oxygen comprises O₂ or N₂O.

31. The method according to claim 27, wherein said delivering step is a remote plasma-enhanced chemical vapor deposition occurring in a reactor, and wherein the remote-plasma-enhanced chemical vapor deposition comprises:
subjecting the gaseous source comprising oxygen to radio-frequency plasma-excitation or microwave frequency plasma-excitation, the gaseous source comprising oxygen further comprising a rare gas element;
wherein the gaseous oxygen-containing source is injected into the reactor upstream relative to the gaseous source comprising aluminum and the gaseous source comprising element M.

32. The method according to claim 27, wherein M is hafnium (Hf) or zirconium (Zr), n is 1, m is 2, j is 4, and k is 1.

33. The method according to claim 27, wherein M is yttrium (Y) or lanthanum (La), n is 2, m is 3, j is 3, and k is 1.

34-46. (Canceled)

47. The method according to claim 4, wherein the gaseous source comprises more that one element including element A, element B or element M, and combinations thereof.

48. The method according to claim 4, wherein said delivering step includes laser-assisted chemical vapor deposition, direct or remote plasma assisted chemical vapor deposition, electron cyclotron resonance chemical vapor deposition, reactive physical vapor deposition or atomic layer deposition.

49. The method according to claim 4, wherein the formation of the non-crystalline oxide occurs in a non-equilibrium environment.

50. The method according to claim 27, wherein the gaseous source comprises more that one element including element A, element B or element M, and combinations thereof.

51. The method according to claim 27, wherein said delivering step includes laser-assisted chemical vapor deposition, direct or remote plasma assisted chemical vapor deposition, electron cyclotron resonance chemical vapor deposition, reactive physical vapor deposition or atomic layer deposition.

52. The method according to claim 27, wherein the formation of the non-crystalline oxide occurs in a non-equilibrium environment.
